(19) United States
(12) Patent Application Publication
(10) Pub. No.: US 2007/0176167 A1
(43) Pub. Date: Aug. 2, 2007

(54) Method of making organic light emitting devices

(75) Inventors: Gautam Parthasarathy, Saratoga Springs, NY (US); Larry Neil Lewis, Scotia, NY (US); Kyle Erik Litz, Ballston Spa, NY (US); Joseph John Shiang, Niskayuna, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company, Schenectady, NY (US)

(21) Appl. No.: 11/341,174

(22) Filed: Jan. 27, 2006

(51) Int. Cl. H01L 29/08

(52) U.S. Cl. 257/40; 257/103; 438/22; 257/E51.018

(57) ABSTRACT

The invention includes embodiments that relate to a method of making an organic light-emitting device comprising at least one bilayer structure. The method comprises providing at least one first layer comprising at least one cross-linkable organic material and at least one photo acid generator; exposing the first layer to a radiation source to afford a cross-linked first layer; and disposing at least one second layer on the cross-linked first layer. The method affords a bilayer structure having an enhanced structural integrity relative to the corresponding bilayer structure in which the first layer is not cross-linked. The invention also includes embodiments that relate to an organic light emitting device.

### STATEMENT REGARDING FEDERALLY SPONSORED RESEARCH & DEVELOPMENT

This invention was made with Government support under contract number DEFC2605NT42343 awarded by Department of Energy. The Government has certain rights in the invention.

### BACKGROUND

The invention includes embodiments that relate to a method of making an organic light-emitting device. The invention also includes embodiments that relate to an organic light-emitting device.

An organic light-emitting device (OLED) is typically a thin film structure formed on a substrate such as glass or transparent plastic. A light-emitting layer (emissive layer) of an organic electroluminiscent material and optional adjacent semiconductor layers are sandwiched between a cathode and an anode to form a multi-layered device. The semiconductor layers may be either hole (positive charge)-injecting or electron (negative charge)-injecting layers and also comprise organic materials. The light emitting organic layer may itself consist of multiple sublayers, each comprising a different organic electroluminiscent material. Upon application of an appropriate voltage to the OLED, the injected positive and negative charges recombine in the emissive layer to produce light.

The fabrication of a multilayered device comprising organic materials has been problematic using methods involving solvents. This is because of dissolution of underlying layers in solutions employed for disposing the succeeding layers. Further, even if the coating compositions do not dissolve the underlying layer, it is often difficult to achieve continuous and coalesced film coverage. Crosslinked organic materials may be used to circumvent this problem. However, organic layers in multilayer organic light emitting devices are typically cross-linked by heating at temperatures above 130 degrees Celsius. In many instances, light emissive materials used in OLEDs cannot be heated to temperatures above 130 degrees Celsius as photoluminescence yield of theses materials may be reduced following such treatment.

Therefore a method of making a multilayered organic light-emitting device having enhanced structural integrity is greatly desired. Moreover, multilayered organic light emitting devices having enhanced structural integrity are also desired.

### BRIEF DESCRIPTION

In one embodiment, the present invention provides a method of making an organic light-emitting device comprising at least one bilayer structure. The method comprises providing at least one first layer comprising at least one cross-linkable organic material and at least one photo acid generator; exposing the first layer to a radiation source to afford a cross-linked first layer; and disposing at least one second layer on the cross-linked first layer. The method affords a bilayer structure having an enhanced structural integrity relative to the corresponding bilayer structure in which the first layer is not cross-linked.

In a second embodiment, the present invention provides a method of making an organic light-emitting device comprising at least one bilayer structure. The method comprises providing at least one first layer comprising at least one cross-linkable organic material and at least one onium salt; exposing the first layer to ultra-violet light source to afford a cross-linked first layer; and disposing at least one second layer on the cross-linked first layer. The method affords a bilayer structure having an enhanced structural integrity relative to the corresponding bilayer structure in which the first layer is not cross-linked.

In a third embodiment, the present invention provides an organic light-emitting device comprising at least one bilayer structure. The bilayer structure comprises a cross-linked first layer comprising a cross-linked organic material and at least one photoacid derived from a photoacid generator; and a second layer disposed on the cross-linked first layer. The bilayer structure has an enhanced structural integrity relative to the corresponding bilayer structure in which the first layer is not cross-linked.

### BRIEF DESCRIPTION OF THE DRAWINGS

FIG. 1 is a cross-sectional representation of a bilayer structure of an organic light emitting device, according to one embodiment of the present invention.

FIG. 2 is a cross-sectional representation of a bilayer structure of an organic light emitting device, according to one embodiment of the present invention.

FIG. 3 is a cross-sectional representation of a bilayer structure of an organic light emitting device, according to one embodiment of the present invention.

FIG. 4 is a cross-sectional representation of a bilayer structure of an organic light emitting device, according to one embodiment of the present invention.

FIG. 5 is a cross-sectional representation of an organic light emitting device, according to one embodiment of the present invention.

FIG. 6 is a graph illustrating the optical density versus number of rinses.

FIG. 7 is a graph illustrating the optical density versus number of rinses.

### DETAILED DESCRIPTION

In the following specification and the claims, which follow, reference will be made to a number of terms, which shall be defined to have the following meanings.

The singular forms “a”, “an” and “the” include plural referents unless the context clearly dictates otherwise.

Approximating language, as used herein throughout the specification and claims, may be applied to modify any quantitative representation that could permissibly vary without resulting in a change in the basic function to which it is related. Accordingly, a value modified by a term or terms, such as “about”, are not to be limited to the precise value specified. In some instances, the approximating language may correspond to the precision of an instrument for measuring the value.

As used herein, the term “disposed over” or “deposited over” means disposed or deposited immediately on top of and in contact with, or disposed or deposited on top of but with intervening layers there between.

As noted, in one embodiment the present invention provides a method of making an organic light-emitting device comprising at least one bilayer structure. The method comprises providing at least one first layer comprising at least one cross-linkable organic material and at least one photo acid generator; exposing the first layer to a radiation source to afford a cross-linked first layer; and disposing at least one second layer on the cross-linked first layer. The method affords a bilayer structure having an enhanced structural integrity relative to the corresponding bilayer structure in which the first layer is not cross-linked.

In one embodiment, the cross-linked first layer is derived from the cross-linkable organic material and comprises a conductive material, an electro-active material, a hole injection material, a hole transport material, a hole blocking material, an electron injection material, an electron transport material, or an electron blocking material.

In one embodiment, the cross-linked first layer comprises an electro-active material. The term “electroactive” as used herein refers to a material that upon application of bias is (1) capable of transporting, blocking or storing charge (either positive charge or negative charge), (2) light-absorbing or light emitting, typically although not necessarily fluorescent, and/or (3) useful in photo-induced charge generation, and/or (4) of changing color, reflectivity, transmittance. In the present context an electro-active layer is a layer, which comprises at least one electro-active organic material. As used herein the term “organic material” may refer to either small molecular organic compounds, or high molecular organic compounds, including but not limited to dendrimers, or large molecular polymers, including oligomers (for example an oligomer comprising from 2 to about 10 repeat units), and polymers comprising more than 10 repeat units. Such materials generally possess a delocalized p-electron system, which typically enables the polymer chains or organic molecules to act as positive and negative charge carriers with relatively high charge mobility.

In one embodiment, the cross-linked first layer comprises a light emissive material and is a light emissive layer. In this and other embodiments, the light emissive layer is the locus of combination of holes and electrons to provide light emissive excited state species which emit electromagnetic radiation, typically in the visible range. Electro-active organic materials that are light emissive may be selected to electroluminesce in the desired wavelength range.

In one embodiment, the light emissive material is derived from a light emissive cross-linkable organic material. Suitable light emissive organic materials which may be employed include, but are not limited to, poly(N-vinylcarbazole) (“PVK”, emitting violet-to-blue light in the wavelengths of about 380-500 nanometers) and its derivatives; polyfluorene (410-550 nanometers) and its derivatives; poly(para-phenylene) (400-550 nanometers) and its derivatives; poly(p-phenylene vinylene); poly(pyridine vinylene); polyquinoxaline; polyquinoline, polysilanes, and copolymers thereof.

Further examples of suitable light emissive organic materials include derivatives of polyfluorene such as poly(alkylfluorene), for example poly(9,9-dihexylfluorene), poly(dioctylfluorene), and poly{9,9-bis(3,6-dioxaheptyl)-fluorene-2,7-diyl}; derivatives of poly(para-phenylene) (PPP) such as poly(2-decyloxy-1,4-phenylene) and poly(2,5-diheptyl-1,4-phenylene); poly(p-phenylene vinylene) (PPV) derivatives such as dialkoxy-substituted PPV, and cyano-substituted PPV; derivatives of polythiophene such as poly(3-alkylthiophene), poly(4,4′-dialkyl-2,2′-bithiophene), and poly(2,5-thienylene vinylene); derivatives of poly(pyridine vinylene); derivatives of polyquinoxaline; and derivatives of polyquinoline. In one particular embodiment a suitable light emitting material is poly(9,9-dioctylfluorenyl-2,7-diyl) end capped with N,N-bis(4-methylphenyl)-4-aniline. Mixtures of polymers and/or copolymers may also be used to tune the color of emitted light, for example.

As noted, another class of suitable organic materials which may be employed as the light emissive material are polysilanes. Typically, polysilanes are linear silicon-backbone polymers substituted with a variety of alkyl and/or aryl groups. Polysilanes are quasi one-dimensional materials with delocalized sigma-conjugated electrons along polymer backbone. Examples of suitable polysilanes include, but are not limited to, poly(di-n-butylsilane), poly(di-n-pentylsilane), poly(di-n-hexylsilane), poly(methylphenylsilane), and poly{bis(p-butylphenyl)silane}.

In certain embodiments, organic materials having molecular weight less than about 5000 grams per mole and comprising one or more aromatic radicals also applicable as light emissive materials. An example of such materials is 1,3,5-tris{N-(4-diphenylaminophenyl)phenylamino}benzene, which emits light in the wavelength range of from about 380 to about 500 nanometers. The light emissive organic layer also may comprise still lower molecular weight organic molecules, such as phenylanthracene, tetraarylethene, coumarin, rubrene, tetraphenylbutadiene, anthracene, perylene, coronene, their derivatives, or a combination of two or more of the foregoing. These materials generally emit light having maximum wavelength of about 520 nanometers. Still other advantageous materials are the low molecular-weight metal organic complexes such as aluminum-, gallium-, and indium-acetylacetonate, which emit light in the wavelength range of from about 415 to about 457 nanometers. Suitable aluminum compounds include aluminum-(picolymethylketone)-bis{2,6-di(t-butyl)phenoxide}. In addition, scandium-(4-methoxy-picolylmethylketone)-bis(acetylacetonate), which emits in the wavelength range of from about 420 to about 433 nanometers may be employed. In certain embodiments, for example white light applications, beneficial light emissive organic materials are those that emit light in the blue-green wavelength range.

The cross-linkable organic material comprises at least one cross-linkable functional group. The cross-linkable functional groups can be activated (i.e. caused to react) upon exposure to a radiation source. As used herein, the term radiation source includes a source of electromagnetic radiation, a source of charged particles such an electron-beam, or a combination thereof. In one embodiment, the electromagnetic radiation has a wavelength in the range from about 1 nm to about 2500 nm.

In one embodiment, the cross-linkable functional groups comprises an acrylate group, a methacrylate group, an epoxy group, an olefinic group, a urethane group, a vinyl ether group, or a combination thereof.

In one embodiment, the present invention provides a method for making an organic light-emitting device comprising at least one bilayer structure. The method comprises providing at least one first layer comprising at least one cross-linkable organic material, wherein the cross-linkable organic material comprises at least one organic light emissive material and a cross-linkable functional group. In another embodiment, the cross-linkable organic material comprises octylfluorene and triarylamine.

As noted, the first layer further comprises a photoacid generator. As used herein, the term photoacid generator refers to a compound which when irradiated generates a photoacid. Suitable examples of photoacid generators include, but are not limited to, onium salts, nitrobenzyl esters, sulfones, phosphates, and sulfonates. Suitable examples of onium salts include, but are not limited to, iodonium salts, sulphonium salts, oxonium salts, halonium salts, and phosphonium salts.

Further examples of photoacid generators which may be suitable for the current invention, include but are not limited to, N-hydroxyimidosulfonates, diphenyliodonium hexafluorophosphate, diazonaphthoquinones, diphenyliodonium triflate, diphenyliodonium p-toluenesulfonate, triarylsulfonium sulfonates, (p-methylphenyl, aquatris(pentaflurophenyl)borate, p-(isopropylphenyl)iodonium tetrakis(pentafluorophenyl)borate, bis(isopropylphenyl)iodonium hexafluoroantimonate, bis(n-dodecylphenyl)iodonium hexafluoroantimonate, and combinations thereof.

In one embodiment, the photoacid generator comprises an onium salt. As used herein the term “onium” refers to a positively charged hypervalent ion of a nonmetallic element. The term onium is not limited to monovalent ions and may include multiply-charged onium ions. In various embodiments the photoacid generator comprises a borate, an iodonium salt, a sulphonium salt, an oxonium salt, a halonium salt, a phosphonium salts, or a combination of two or more of the foregoing photoacid generators. In particular embodiments, the photoacid generator comprises aquatris(pentafluorphenyl) borate, diphenyliodonium hexafluorophosphate, diphenyliodonium triflate, diphenyliodonium p-toluenesulfonate, triphenylsulfonium sulfonate, p-(isopropylphenyl)iodonium tetrakis(pentafluorophenyl)borate, bis(isopropylphenyl)iodonium hexafluoroantimonate, bis(n-dodecylphenyl)iodonium hexafluoroantimonate, or a combination of two or more of the foregoing photoacid generators.

In one embodiment, the photo acid generator is present in an amount corresponding to from about 0.1 weight percent to about 50 weight percent of the cross-linkable organic material. In another embodiment, the photo acid generator is present in an amount corresponding to from about 10 weight percent to about 40 weight percent of the cross-linkable organic material. In yet another embodiment, the photo acid generator is present in an amount corresponding to from about 20 weight percent to about 30 weight percent of the cross-linkable organic material.

In one embodiment, the first layer is provided using a method comprising coating, extrusion, lithographic printing, Langmuir processing, flash evaporation, sputtering, vapor deposition or a combination of two or more of the foregoing techniques. Suitable coating methods include, but are not limited to, spin coating, dip coating, reverse roll coating, wire-wound or Mayer rod coating, direct gravure coating, offset gravure coating, slot die coating, blade coating, hot melt coating, curtain coating, knife over roll coating, extrusion, air knife coating, spray, rotary screen coating, multilayer slide coating, meniscus coating, comma coating, and microgravure coating. Suitable vapor deposition methods include, but are not limited to, plasma-enhanced chemical-vapor deposition (“PECVD”), radio-frequency plasma-enhanced chemical-vapor deposition (“RFPECVD”), expanding thermal-plasma chemical-vapor deposition (“ETPCVD”), electron-cyclotron-resonance plasma-enhanced chemical-vapor deposition (ECRPECVD”), or inductively coupled plasma-enhanced chemical-vapor deposition (“ICPECVD”). Suitable sputtering methods include, but are not limited to reactive sputtering.

In one embodiment, the first layer is provided by spin-coating. Thus, in one embodiment, a solution of a cross-linkable organic material and a photoacid generator in the required amount is prepared and spin-coated onto a surface (for example an electrode surface) to provide the first layer. Any suitable solvent may be used to prepare the solution of a cross-linkable organic material and a photo-acid generator. Suitable solvents include hydrocarbons such as o-xylene, m-xylene, p-xylene, toluene, hexanes, like solvents, and combinations of two or more of the foregoing solvents. A solution of the cross-linkable organic material and a photoacid generator may be prepared by using a stirrer, by ultrasonication, or by any other method known to one of ordinary skill in the art

In one embodiment, the first layer has a thickness in a range from about 10 nanometers to about 1000 nanometers. In another embodiment, the first layer has a thickness in a range from about 30 nanometers to about 600 nanometers. In yet another embodiment, the first layer has a thickness in a range from about 60 nanometers to about 300 nanometers.

As noted, the method for making the organic light-emitting device comprises exposing the first layer to a radiation source. In one embodiment, the radiation source is selected from the group consisting of ultra-violet radiation sources, gamma radiation sources, plasma radiation sources, electron-beam sources, and combinations thereof. In a particular embodiment, the method for making the organic light-emitting device comprises exposing the first layer to an ultra violet radiation source.

Exposure of the first layer to the radiation source results in formation of a cross-linked first layer. Without being bound by any theory, it is believed that the photoacid generated from the photoacid generator upon exposure to a radiation source aids in the cross-linking of the cross-linkable organic material.

The method for making the organic light-emitting device comprises disposing a second layer on the cross-linked first layer. In one embodiment, the second layer is a conductive layer, an electro-active layer, a hole injection layer, a hole transport layer, a hole blocking layer, an electron injection layer, an electron transport layer, or an electron blocking layer.

In one embodiment, the second layer comprises a hole injection material, a hole transport material, a hole blocking material, an electron injection material, an electron transport material, or an electron blocking material. As used herein, hole transport materials and electron transport materials may be collectively referred to as charge transport materials. As used herein, hole injection materials and electron injection materials may be collectively referred to as charge injection materials. As used herein, hole blocking material and electron blocking material may be collectively referred to as charge blocking materials.

In one embodiment, the second layer comprises a charge transport material. In another embodiment, the second layer comprises a charge injection material. In yet another embodiment, the second layer comprises a charge blocking material.

Non-limiting examples of charge transport materials include low-to-intermediate molecular weight (for example, less than about 200,000) organic molecules, for example poly(3,4-ethylenedioxythiophene) (PEDOT), polyaniline, poly(3,4-propylenedioxythiophene) (PPropOT), polystyrenesulfonate (PSS), polyvinyl carbazole (PVK), like materials, and combinations of two or more of the foregoing.

As noted, the method of making the organic light-emitting device comprises disposing a second layer on the cross-linked first layer. In one embodiment, the method of disposing the second layer on the cross-linked first layer comprises exposing said cross-linked first layer to a solvent, for example by solvent-casting, spin-coating, dip coating, spray coating, blade coating, or a combination of two or more of the foregoing techniques.

Exposing said cross-linked first layer to a solvent results in the cross-linked first layer being in contact with the solvent for a period of time, sometimes referred to herein as the contact time. The contact time of the solvent with the cross-linked first layer may vary depending upon the method of disposing of the second layer. Thus, the contact time of the solvent with the cross-linked first layer may be on the order of a few seconds, for example, when the second-layer is disposed on the cross-linked first by spin-coating. In the alternative, the contact time of the solvent with the cross-linked first layer may be on the order of a few hours, for example, when the second-layer is disposed on the cross-linked first by solution-casting. In one specific embodiment, the method of disposing the second layer on the cross-linked first layer comprises spin-coating.

The solvent may be a polar or a non polar solvent and may comprise one or more suitable solvents that may be used to dispose the second layer on the cross-linked first layer. In one embodiment, para-xylene is used as a solvent to dispose the second layer on the cross-linked first layer.

As noted, the present invention provides a method for making an organic-light emitting device comprising a bilayer structure having a cross-linked first layer such that the bilayer structure has enhanced structural integrity relative to a corresponding bilayer structure in which the first layer is not cross-linked. The term “structural integrity” of the bilayer structure includes non-dissolution and/or non-disintegration of the first layer upon exposure to the solvent used or disposing the second layer. Typically, when the second layer is applied in a solvent to the cross-linked first layer, the resultant bilayer structure exhibits enhanced structural integrity in the sense that the bilayer structure comprises two distinct layers, the cross-linked first layer and the second layer, as a result of relatively little dissolution of the first cross-linked layer occurring during the application of the second layer.

The structural integrity of the bilayer structure may be qualitatively or quantitatively determined. Qualitative determination of the structural integrity of the bilayer structure may be carried out by visual inspection of the surface of the bilayer structure. As noted, and without wishing to be bound by any theory, it is believed that exposing a first layer that is not cross-linked to a solvent when disposing the second layer leads to disintegration, dissolution, swelling, and/or distortion of the first layer. Such effects may result in uneven second layer coverage, a non uniform surface, or other undesired outcome.

The structural integrity of the bilayer structure comprising a cross-linked first layer relative to a bilayer structure comprising a first layer that is not cross-linked may also be determined quantitatively. Quantitative determination of structural integrity may be carried out by direct or indirect measurement of a specific characteristic of the bilayer structure. One example of a direct quantitative determination of structural integrity includes measurement of the thickness of the bilayer structure by any method known to one of ordinary skill in the art. If the structural integrity of the component first layer of the bilayer structure is compromised while disposing the second layer, the thickness of the first layer may vary leading to variations in the thickness of the bilayer structure. Alternatively, the structural integrity of the bilayer structure may be determined indirectly, for example by measuring the optical density of the bilayer structure. For films, the optical density is approximately linearly proportional to film thickness. Thus, optical density may be used to gauge the layer thickness in a rapid noninvasive manner. As noted, if the structural integrity of the first layer of the bilayer structure is compromised while disposing the second layer, the thickness of the first layer may vary resulting in variation in optical density at various points on the bilayer structure. Thus, in one embodiment, the structural integrity of the bilayer structure is determined by measuring the optical density of the bilayer structure at multiple locations on the bilayer structure.

As will be appreciated by those of ordinary skill in the art, various configurations of the bilayer structure may be possible. As noted, the first layer may be a conductive layer, an electro-active layer, a hole injection layer, a hole transport layer, a hole blocking layer, an electron injection layer, an electron transport layer, or an electron blocking layer. Similarly, the second layer may be a conductive layer, an electro-active layer, a hole injection layer, a hole transport layer, a hole blocking layer, an electron injection layer, an electron transport layer, or an electron blocking layer

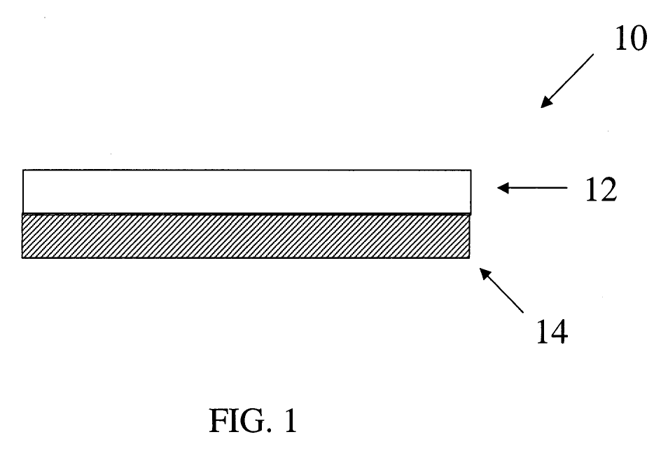

In one embodiment, the bilayer structure of the present invention comprises a cross-linked first layer that is a light emissive layer and a second layer that is either a charge blocking layer, a charge transport layer, or a charge-injection enhancement layer. Referring to FIG. 1, a first exemplary embodiment of a bilayer structure 10 of an organic light emitting device is illustrated. In the illustrated embodiment, the bilayer structure 10 is shown to include a cross-linked first layer 12 and a second layer 14. In a non-limiting example, the cross-linked first layer 12 is a light emissive layer and the second layer 14 is one of a charge blocking layer, a charge transport layer, or a charge-injection enhancement layer.

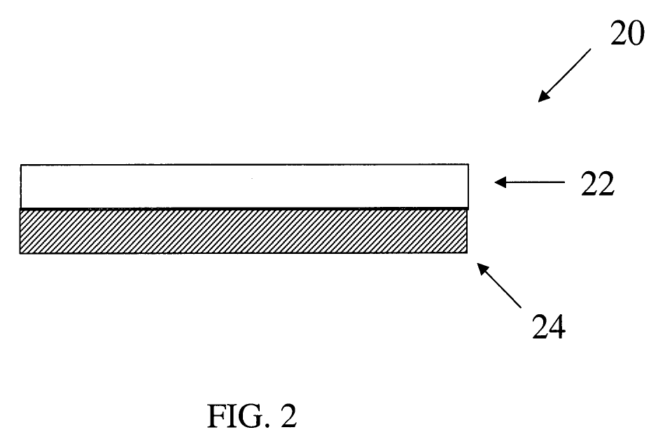

In another alternative embodiment, the bilayer structure of the present invention comprises a cross-linked first layer that is either a charge blocking layer, a charge transport layer, or a charge-injection enhancement layer and a second layer that is a light emissive layer. Referring to FIG. 2, a second exemplary embodiment of a bilayer structure 20 of an organic light emitting device is illustrated. In the illustrated embodiment, the bilayer structure 20 is shown to include a cross-linked first layer 22 and a second layer 24. In a non-limiting example, the cross-linked first layer 22 is one of a charge blocking layer, a charge transport layer, or a charge-injection enhancement and the second layer 24 is a light emissive layer.

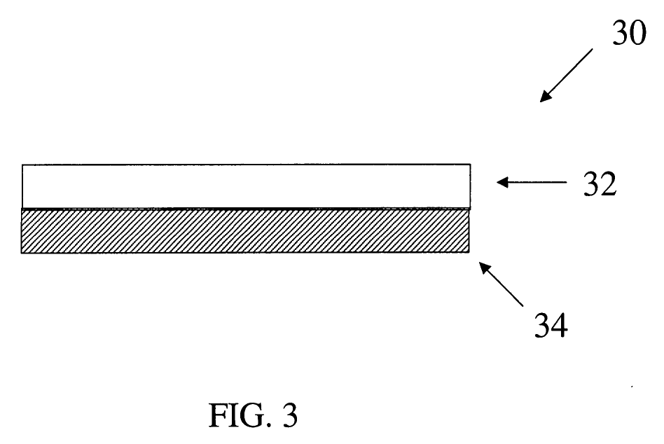

It may also be possible that the bilayer structure may comprise more than one electro-active organic layer formed successively, one on top of another. Each layer may have a different electro-active organic material that may emit in a different wavelength range. Thus, in one embodiment, the bilayer structure of the present invention comprises a cross-linked first layer that is a light emissive layer and a second layer that is also a light emissive layer. The second layer may comprise an electroluminiscent organic material that may be different from that of the first layer. Referring to FIG. 3, a third exemplary embodiment of a bilayer structure 30 of an organic light emitting device is illustrated. In the illustrated embodiment, the bilayer structure 30 is shown to include a cross-linked first layer 32 and a second layer 34. In a non-limiting example, the cross-linked first layer 32 is a light emissive layer and the second layer 34 is also a light emissive layer.

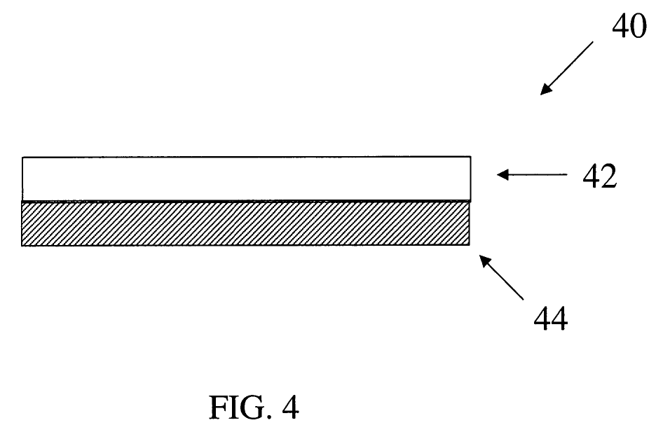

In another embodiment, the bilayer structure of the present invention comprises a cross-linked first layer that is one of a charge blocking layer, a charge transport layer, or a charge-injection enhancement layer and a second layer that is also one of a one of a charge blocking layer, a charge transport layer, or a charge-injection enhancement layer. Referring to FIG. 4, a fourth exemplary embodiment of a bilayer structure 40 of an organic light emitting device is illustrated. In the illustrated embodiment, the bilayer structure 40 is shown to include a cross-linked first layer 42 and a second layer 44. In a non-limiting example, the cross-linked first layer 42 is one of a charge blocking layer, a charge transport layer, or a charge-injection enhancement layer and the second layer 44 is also one of a charge blocking layer, a charge transport layer, or a charge-injection enhancement layer.

The organic light emitting device may further include one or more layers such as a hole transport layer, a hole injection layer, an electron transport layer, an electron injection layer, an electroluminescent layer, a conductive layer or any combinations thereof.

The organic light emitting device may further include a substrate layer such as but not limited to polymeric substrates. Non limiting examples of substrates include thermoplastic polymers, for example poly(ethylene terephthalate), poly(ethylene naphthalate), polyethersulfones, polycarbonates, polyimides, polyetherimides, polyacrylates, and polyolefins; glass; metal; like materials; and combinations thereof.

The organic light emitting device provided by the present invention comprise includes conductive layers such as a cathode layer and an anode layer.

A cathode layer serves the purpose of injecting negative charge carriers (electrons) into the electro-active organic layer. Suitable cathode materials for organic light emitting devices typically include materials having low work function value. Non-limiting examples of suitable cathode materials include materials such as K, Li, Na, Mg, Ca, Sr, Ba, Al, Ag, Au, In, Sn, Zn, Zr, Sc, Y, Mn, Pb, elements of the lanthanide series, metal alloys (particularly Ag—Mg alloy, Al—Li alloy, In—Mg alloy, Al—Ca alloy, and Li—Al alloy), and mixtures thereof. Other examples of suitable cathode component materials may include alkali metal fluorides, alkaline earth fluorides, and mixtures of metal fluorides. Indium tin oxide, tin oxide, indium oxide, zinc oxide, indium zinc oxide, zinc indium tin oxide, antimony oxide, carbon nanotubes, and mixtures of two or more of the foregoing are also suitable cathode materials. In one embodiment, the cathode comprises at least two layers. A cathode having two layers is at times referred to as a bilayer cathode. Non-limiting examples of bilayer cathodes are illustrated by cathodes having an inner layer comprising LiF or NaF and an outer layer of aluminum or silver, and cathodes having an inner layer of calcium and an outer layer of aluminum or silver. Bilayer cathodes comprising a metal fluoride are believed to exhibit enhanced electron injection relative to the corresponding monolayer cathode lacking the metal fluoride.

An anode layer serves the purpose of injecting positive charge carriers (holes) into the electro-active organic layer. Suitable anode materials for electro-active devices typically include those having a high work function value and may generally include a material having a bulk conductivity of at least 100 siemens per centimeter, as measured by a four-point probe technique. Non-limiting examples of anode materials include, but are not limited to, indium tin oxide (ITO), tin oxide, indium oxide, zinc oxide, indium zinc oxide, nickel, gold, like materials, and mixtures thereof. Indium tin oxide (ITO) is typically used for this purpose because it is substantially transparent to light transmission and thus enables light emitted from electro-active organic layer to escape through the ITO anode layer without being significantly attenuated. The term “transparent” means allowing at least 50 percent, commonly at least 80 percent, and more commonly at least 90 percent, of incident light in the visible wavelength range having an angle of incidence of less than about 10 degrees to be transmitted.

Typically, during fabrication the anode and cathode layers are deposited on an underlying layer(s) by physical vapor deposition, chemical vapor deposition, sputtering, or other process known to those skilled in the art. The thickness of cathode and anode layers may vary independently but are generally in the range from about 10 nanometers to about 500 nanometers in an embodiment, from about 10 nanometers to about 200 nanometers in another embodiment, and from about 50 nanometers to about 200 nanometers in still another embodiment.

In one embodiment of the present invention, a hole transport and/or hole blocking layer is included in the organic light emitting device. The hole transport layer transports holes and blocks the transportation of electrons so that holes and electrons are substantially optimally combined in the light emissive layer. Non-limiting examples of hole transport layer materials include triaryldiamine, tetraphenyldiamine, aromatic tertiary amines, hydrazone derivatives, carbazole derivatives, triazole derivatives, imidazole derivatives, oxadiazole derivatives having an amino group, polythiophenes, and like materials. Suitable materials for a hole blocking layer comprise poly(N-vinyl carbazole), and like materials.

In one embodiment of the present invention, a hole injection enhancement layer is included in the organic light emitting device to provide a higher injected current at a given forward bias and/or a higher maximum current before the failure of the device. Thus, the hole injection enhancement layer facilitates the injection of holes from the anode. Non-limiting examples of hole injection enhancement layer materials include arylene-based compounds such as 3,4,9,10-perylenetetra-carboxylic dianhydride, bis(1,2,5-thiadiazolo)-p-quinobis(1,3-dithiole), and like materials.

In one embodiment of the present invention, an electron injection and transport enhancement layer is included in the organic light emitting device. Materials suitable for the electron injection and transport enhancement layer materials and electron transport layer materials include metal organic complexes such as oxadiazole derivatives, perylene derivatives, pyridine derivatives, pyrimidine derivatives, quinoline derivatives, quinoxaline derivatives, diphenylquinone derivatives, nitro-substituted fluorene derivatives, and like materials.

In one embodiment, the organic light-emitting device can further comprise one or more photoluminescent (“PL”) layers, having at least a fluorescent layer and/or a phosphorescent layer, such as, for example those disclosed in U.S. Pat. No. 6,847,162.

Organic light emitting devices of the present invention may include additional layers such as, but not limited to, one or more of an abrasion resistant layer, an adhesion layer, a chemically resistant layer, a photoluminescent layer, a radiation-absorbing layer, a radiation reflective layer, a barrier layer, a planarizing layer, optical diffusing layer, and combinations thereof.

In some embodiments, the method of making the organic light emitting device of the present invention includes providing a substrate and disposing at least one bilayer structure over the substrate, wherein the bilayer structure layer comprises a cross-linked first layer and second layer. In certain embodiments, the substrate is an electrode and may be a cathode or an anode. The electrode substrate may include, in addition to the electrode material itself, one or more other substrate materials such the polymeric, glass and metal substrates listed hereinabove.

In one embodiment, the method comprises disposing over the substrate a hole transport layer, a hole injection layer, an electron transport layer, an electron injection layer, a photoabsorption layer, a conductive layer, an electroluminescent layer, or any combination thereof, prior to disposing the bilayer structure. In some embodiments, the bilayer structure is in direct contact with the substrate and the method may further comprise disposing over the bilayer structure a hole transport layer, a hole injection layer, an electron transport layer, an electron injection layer, a photoabsorption layer, a conductive layer, an electroluminescent layer, or any combination thereof. In some embodiments, the method includes laminating together bilayer or multilayer structures, with at least one bilayer structure including a cross-linked first layer and a second layer.

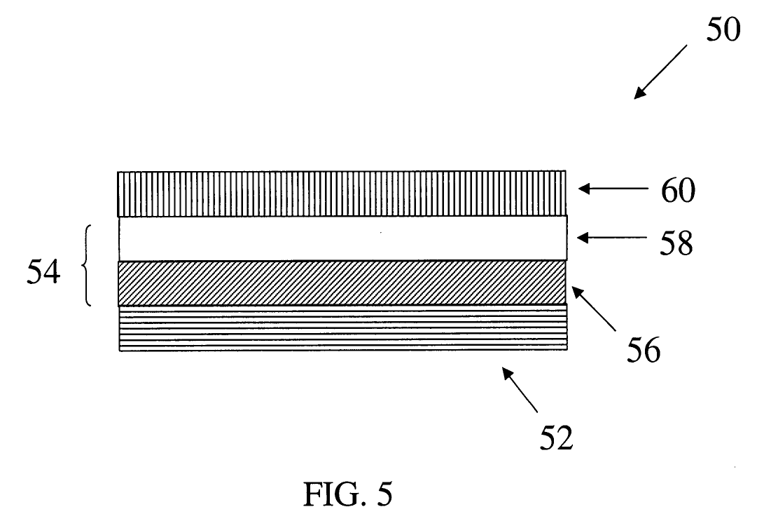

According to one exemplary embodiment, an organic light emitting device 50 made by a method of the present invention is illustrated in FIG. 5. The organic light emitting device 50 comprises an anode layer 52; a bilayer structure 54, wherein the bilayer structure 54 comprises a cross-linked first layer 56 and a second layer 58; and a cathode layer 60. The cross-linked first layer and the second layer independently comprises one of a conductive layer, an electro-active layer, a hole injection layer, a hole transport layer, a hole blocking layer, an electron injection layer, an electron transport layer, or an electron blocking layer. As will be appreciated by one of ordinary skill in the art, in alternate embodiments of the present invention, one or more of other layers may be present between the anode layer 52 and the bilayer structure 54 and/or the bilayer structure 54 and the cathode layer 60.

Depositing or disposing one or more of the afore-mentioned layer(s) may be carried out using techniques such as, but not limited to, spin coating, dip coating, reverse roll coating, wire-wound or Mayer rod coating, direct and offset gravure coating, slot die coating, blade coating, hot melt coating, curtain coating, knife over roll coating, extrusion, air knife coating, spray, rotary screen coating, multilayer slide coating, coextrusion, meniscus coating, comma coating, reverse gravure coating, micro gravure coating, lithographic processes, Langmuir Blodgett processing, flash evaporation, vapor deposition, plasma-enhanced chemical-vapor deposition (“PECVD”), radio-frequency plasma-enhanced chemical-vapor deposition (“RFPECVD”), expanding thermal-plasma chemical-vapor deposition (“ETPCVD”), sputtering including, but not limited to, reactive sputtering, electron-cyclotron-resonance plasma-enhanced chemical-vapor deposition (ECRPECVD”), inductively coupled plasma-enhanced chemical-vapor deposition (“ICPECVD”), like techniques, and a combination of two or more of the foregoing coating/deposition methods.

In one embodiment, the present invention provides a method of making an organic light-emitting device comprising at least one bilayer structure. The method comprises providing at least one first layer comprising at least one cross-linkable organic material and at least one onium salt; exposing the first layer to an ultraviolet radiation source to afford a cross-linked first layer; and disposing at least one second layer on the cross-linked first layer. The method affords a bilayer structure having an enhanced structural integrity relative to the corresponding bilayer structure in which the first layer is not cross-linked.

In another embodiment, the present invention provides an organic light-emitting device comprising at least one bilayer structure. The bilayer structure comprises a cross-linked first layer comprising a cross-linked organic material and at least one photoacid derived from a photoacid generator; and a second layer disposed on the cross-linked first layer. The bilayer structure has an enhanced structural integrity relative to the corresponding bilayer structure in which the first layer is not cross-linked.

### EXAMPLES

Materials: In the following examples poly(3,4-ethylenedioxythiophene) (PEDOT) was obtained from Stark and TFB was obtained from Dow Sumitomo Chemicals. Details about TFB (also referred to as may be found in U.S. Patent Application 20050014926 paragraphs [0043] and [0062]-[0069] of which are incorporated herein by reference. The photoacid generators aquatris(pentafluorophenyl)borate (CAS No. 155962-45-1 hereinafter referred to as “photoacid generator-1”) and bis(n-dodecylphenyl)iodonium hexafluoroantimonate (CAS No. 71786-70-4, hereinafter referred to as “photoacid generator-2”) were obtained from Aldrich Chemicals and Gelest.

FABRICATION: In the following examples a substructure of an OLED was fabricated as follows. Quartz slides were cleaned in detergent and then baked at 150 degrees Celsius for 10 minutes. Immediately afterwards, the slides were blown dry and placed into an ultraviolet ozone cleaning oven for 10 minutes. Following the ultraviolet-ozone cleaning, a layer of PEDOT having a thickness of approximately 750 angstroms was deposited by spin coating onto the slides and they were then placed on a hot plate at 180 degrees Celsius for 30 minutes.

### Comparative Example 1

### Preparation of an OLED Substructure Comprising an Untreated TFB Layer

Following the fabrication of a PEDOT coated quartz substrate, a solution of TFB in para-xylene was spin-coated onto the PEDOT coated quartz substrate. The thickness of the resultant TFB layer was approximately 300 angstroms and was coated by spin-coating at about 3000 rpm. The solution of TFB in para-xylene for coating onto the PEDOT coated quartz substrate was prepared as follows: A 1 weight percent solution of TFB in para-xylene was prepared by stirring the TFB in para-xylene (p-xylene) for 60 minutes while heating at 80 degrees Celsius. The solution was then allowed to cool down for a period of about 20 minutes prior to spin-coating. Hereinafter, the resulting OLED substructure is referred to as Sample 1.

### Comparative Example 2

### Preparation of an OLED Substructure Comprising a TFB Layer Heated to 180 Degrees Celsius

Following the fabrication of a PEDOT coated quartz substrate, a solution of TFB in para-xylene was spin-coated onto the PEDOT coated quartz substrate as in Comparative Example 1. The thickness of the resultant TFB layer was approximately 300 angstroms. Following spin-coating, the bilayer structure comprising the TFB layer and the PEDOT layer was baked on a hot plate in a wet hood for 60 minutes at 180 degrees Celsius. Hereinafter, the resulting OLED substructure is referred to as Sample 2.

### Comparative Example 3

### Preparation of an OLED Substructure Comprising a TFB Layer Irradiated with Ultraviolet Radiation

Following the fabrication of a PEDOT coated quartz substrate, a solution of TFB in para-xylene was spin-coated onto the PEDOT coated quartz substrate as in Comparative Example-1. The thickness of the TFB layer was approximately 300 angstroms. Following spin-coating, the bilayer structure comprising the TFB layer and the PEDOT layer was exposed to a UV lamp in the hood for a time period of about 5 minutes. Hereinafter, the resulting OLED substructure is referred to as Sample 3.

### Comparative Example 4

### Preparation of an OLED Substructure Comprising a TFB Layer Irradiated with Ultraviolet Radiation and Heated to 180 Degrees Celsius

Following the fabrication of a PEDOT coated quartz substrate, a solution of TFB in para-xylene was spin-coated onto the PEDOT coated quartz substrate as in Comparative Example-1. The thickness of the TFB layer was approximately 300 angstroms. Following spin-coating, the bilayer structure comprising the TFB layer and the PEDOT layer was exposed to a UV lamp in the hood for a time period of about 5 minutes followed by baking on a hot plate in a wet hood for 60 minutes at 180 degrees Celsius. Hereinafter, the resulting OLED substructure is referred to as Sample 4.

### Example 1

### Preparation of an OLED Substructure Comprising an Irradiated Cross-Linked TFB Layer Using the Photoacid Generator-1

Following the fabrication of a PEDOT coated quartz substrate (See FABRICATION), a solution of TFB and photoacid generator-1 in para-xylene was spin-coated onto the PEDOT coated quartz substrate. The thickness of the TFB film was approximately 300 angstroms and was coated by spin-coating at about 3000 rpm. The solution of TFB and photoacid generator-1 in para-xylene was prepared by heating a mixture of TFB and photoacid generator-1 in para-xylene for 60 minutes at 80 degrees Celsius while stirring. The solution comprised about 1 percent by weight TFB. The photoacid generator-1 was present in an amount corresponding to about approximately 30 weight percent of the weight of the TFB. The solution was allowed to cool down for a period of about 20 minutes prior to spin-coating. Following spin-coating, the bilayer structure comprising the layer containing TFB and photoacid generator-1, and the PEDOT layer was exposed to a UV lamp in the hood for a time period of about 5 minutes. Hereinafter, the resulting OLED substructure is referred to as Sample 5.

### Example 2

### Preparation of an OLED Substructure Comprising an Irradiated Cross-Linked TFB Layer Using the Photoacid Generator-2

Following the fabrication of a PEDOT coated quartz substrate; a solution of a blend of TFB and photoacid generator-2 in para-xylene was spin-coated onto the PEDOT coated quartz substrate. The thickness of the resultant TFB film was approximately 300 angstroms and was coated by spin-coating at about 3000 rpm. The solution of TFB and photoacid generator-2 in para-xylene was prepared as in Example 1. Following spin-coating, the bilayer structure comprising the layer containing TFB and photoacid generator-2, and the PEDOT layer was exposed to a UV lamp in the hood for a time period of about 5 minutes. Hereinafter, the resulting OLED substructure is referred to as Sample 6.

MEASUREMENT OF OPTICAL DENSITY: Samples 1-6 were subjected to multiple rinses in p-xylene as follows. The sample (e.g. Sample 1) was placed on top of the spinner and the surface was flooded with p-xylene starting from the center and moving outwards radially. The spinner was started immediately after the substrate was flooded with no delay. This was meant to simulate the fabrication of multiple solution processed polymer layers. Each of Samples 1-6 was subjected to three rinses. Before each rinse the optical density at 390 nm was measured with an HP 8145 optical spectrophotometer. Optical density, being approximately linearly proportional to film thickness, was taken as a measure the bilayer thickness and structural integrity in Samples 1-6.

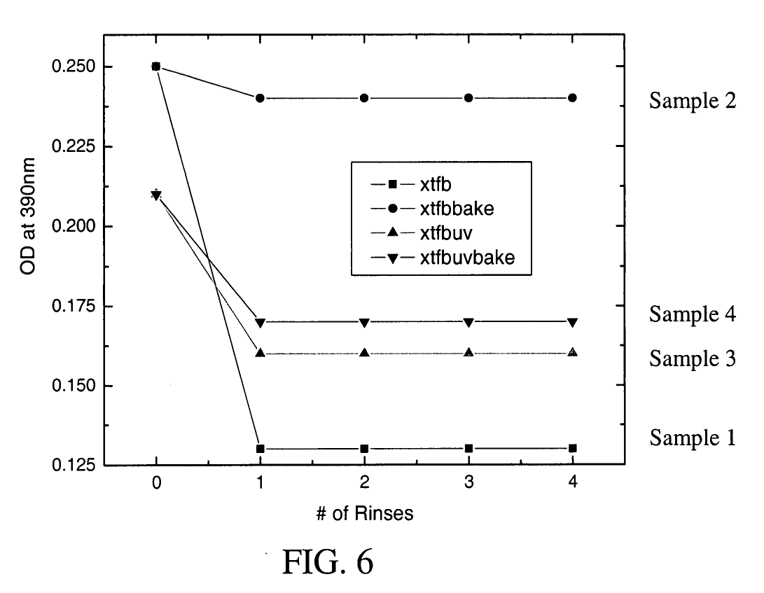

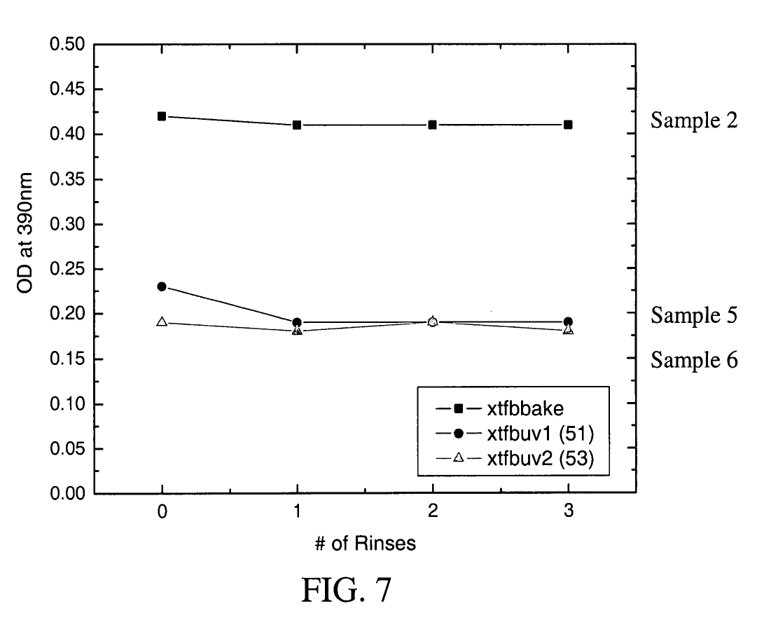

The optical density as a function of number of rinses for Samples 1-4 (Comparative Examples 1-4) is plotted in FIG. 6, and for Samples 5-6 (Examples 1-2) in FIG. 7 respectively. Referring to FIG. 6, it can be seen that if the bilayer comprising PEDOT and TFB alone is not baked (Sample 1) it does not exhibit stable optical density indicating that the TFB remains soluble in para-xylene and does not form an insoluble, cross-linked layer. In Sample 1, most of the film (estimated at greater than 90 percent) is rapidly washed off the quartz substrate after 1 rinse. However, when the bilayer comprising PEDOT and TFB is baked for 60 minutes at 180 degrees Celsius (Sample 2), the film thickness is barely affected (less than 5 percent) after multiple rinses indicative of cross-linking. While the precise nature of the cross linking mechanism is unknown, the temperature required to effect complete cross-linking is greater than 180 degrees Celsius in the time period employed (30 minutes). As noted, this temperature is unacceptably high for the light-emitting polymers typically employed in OLED devices as their photoluminescence efficiency may drop precipitously following exposure to temperatures greater than about 130 degrees Celsius. Comparative Examples 1 and 2 are meant to illustrate and emphasize the desirability of cross-linking effects at temperatures less than 180 degrees. Comparative Examples 3 and 4 illustrate the importance of the presence of the photoacid generator. Even after exposure of the TFB film to ultraviolet radiation (Samples 3 and 4), the film retained only about 50 percent of its original optical density following para-xylene rinsing.

Referring to FIG. 7, it can be seen that that the optical density characteristics of the film obtained by baking (Sample 2) could be duplicated by incorporating a photoacid generator in the TFB film and exposing the film to ultraviolet radiation (Samples 5 and 6). FIG. 7 shows that although the initial film thicknesses are not the same (presumably due to the presence of the photoacid generator in the blend), the degree to which optical density was retained after multiple rinses was similar to that observed for the sample baked at 180 degrees Celsius (Comparative Example-2, Sample 2), that is, less than 5 percent loss of optical density.

While the invention has been illustrated and described in typical embodiments, it is not intended to be limited to the details shown, since various modifications and substitutions can be made without departing in any way from the spirit of the present invention. As such, further modifications and equivalents of the invention herein disclosed may occur to persons skilled in the art using no more than routine experimentation, and all such modifications and equivalents are believed to be within the spirit and scope of the invention as defined by the following claims.

1. A method of making an organic light-emitting device comprising at least one bilayer structure, said method comprising:
providing at least one first layer comprising at least one cross-linkable organic material and at least one photo acid generator;
exposing the first layer to a radiation source to afford a cross-linked first layer; and
disposing at least one second layer on the cross-linked first layer;
to afford a bilayer structure having an enhanced structural integrity relative to the corresponding bilayer structure in which the first layer is not cross-linked.

2. The method according to claim 1, wherein said cross-linked first layer is a conductive layer, an electro-active layer, a hole injection layer, a hole transport layer, a hole blocking layer, an electron injection layer, an electron transport layer, or an electron blocking layer.

3. The method according to claim 1, wherein said cross-linked first layer comprises an electro-active material.

4. The method according to claim 1, wherein said cross-linked first layer comprises a light emissive material.

5. The method according to claim 1, wherein said cross-linkable organic material comprises poly(N-vinylcarbazole), polyfluorene, poly(para-phenylene), poly(p-phenylene vinylene), poly(pyridine vinylene), polyquinoxaline; polyquinoline, polysilane, or copolymers thereof.

6. The method according to claim 5, wherein said cross-linkable organic material further comprises an acrylate group, a methacryalte group, an epoxy group, a styrene group, a urethane group, a vinyl ether group, or a combination thereof.

7. The method according to claim 1, wherein said photo acid generator comprises an onium salt.

8. The method according to claim 1, wherein said photo acid generator comprises an iodonium salt, a sulfonium salt, an oxonium salt, a halonium salt, a phosphonium salt, or a combination thereof.

9. The method according to claim 1, wherein said photo acid generator is present in an amount corresponding to from about 1 weight percent to about 50 weight percent of the cross-linkable organic material.

10. The method according to claim 1, wherein said second layer is a conductive layer, an electro-active layer, a hole injection layer, a hole transport layer, a hole blocking layer, an electron injection layer, an electron transport layer, or an electron blocking layer.

11. The method according to claim 1, wherein said second layer comprises a hole injection material, a hole transport material, a hole blocking material, an electron injection material, an electron transport material, or an electron blocking material.

12. The method according to claim 1, wherein said second layer comprises poly(3,4-ethylenedioxythiophene), polyaniline, poly(3,4-propylenedioxythiophene), polystyrenesulfonate, polyvinyl carbazole, or combinations thereof

13. The method according to claim 1, wherein said radiation source is selected from the group consisting of visible light sources, ultra-violet light sources, gamma radiation sources, electron-beam sources, and combinations thereof.

14. The method according to claim 1, wherein said disposing of the second layer comprises exposing said cross-linked first layer to a solvent.

15. The method according to claim 1, wherein said disposing of the second layer comprises solvent-casting, spin-coating, dip coating, spray coating, blade coating, or a combination thereof.

16. The method according to claim 1, wherein said disposing of the second layer comprises spin-coating.

17. The method according to claim 1, wherein the bilayer structure comprises a light emissive layer and a charge transporting layer.

18. The method according to claim 1, wherein the organic light-emitting device further comprises a cathode layer, an anode layer, an electro-active layer, a hole injection layer, a hole transport layer, a hole blocking layer, an electron injection layer, an electron transport layer, an electron blocking layer, or a combination thereof.

19. A method of making an organic light-emitting device comprising at least one bilayer structure, said method comprising:
providing at least one first layer comprising at least one cross-linkable organic material and at least one onium salt;
exposing the first layer to ultra-violet light source to afford a cross-linked first layer; and
disposing at least one second layer on the cross-linked first layer;
to afford a bilayer structure having an enhanced structural integrity relative to the corresponding bilayer structure in which the first layer is not cross-linked.

20. An organic light-emitting device comprising at least one bilayer structure, said bilayer structure comprising:
a cross-linked first layer comprising a cross-linked organic material and at least one photoacid; and
a second layer disposed on the cross-linked first layer;
wherein the bilayer structure has an enhanced structural integrity relative to the corresponding bilayer structure in which the first layer is not cross-linked.

21. The organic light-emitting device according to claim 20, wherein said cross-linked first layer is a conductive layer, an electro-active layer, a hole injection layer, a hole transport layer, a hole blocking layer, an electron injection layer, an electron transport layer, or an electron blocking layer.

22. The organic light-emitting device according to claim 20, wherein said second layer is a conductive layer, an electro-active layer, a hole injection layer, a hole transport layer, a hole blocking layer, an electron injection layer, an electron transport layer, or an electron blocking layer.

23. The organic light-emitting device according to claim 20, wherein said bilayer structure comprises an electro-active layer and a charge transporting layer.

24. The organic light-emitting device according to claim 1, wherein said photo acid is derived from an onium salt.
